(19) United States
(12) Patent Application Publication
(10) Pub. No.: US 2016/0380021 A1
(43) Pub. Date: Dec. 29, 2016

(54) RADIATION DETECTING DEVICE AND METHOD FOR MANUFACTURING RADIATION DETECTING DEVICE

(71) Applicant: FUJIFILM CORPORATION, Tokyo (JP)

(72) Inventor: Takaaki ITO, Kanagawa (JP)

(21) Appl. No.: 15/257,919

(22) Filed: Sep. 7, 2016

Related U.S. Application Data
(63) Continuation of application No. PCT/JP2015/058599, filed on Mar. 20, 2015.

(30) Foreign Application Priority Data
Mar. 28, 2014 (JP) 2014-070543

(51) Int. Cl. H01L 27/146

(52) U.S. Cl. CPC H01L 27/14663; H01L 27/1462; H01L 27/14685

(57) ABSTRACT

In a radiation detecting device, a groove portion is provided in a sealing region on a photoelectric conversion substrate. The groove portion is provided in the vicinity of a phosphor layer formed on the photoelectric conversion substrate or along an outer peripheral side thereof. A moisture-proof protective layer is provided to cover the phosphor layer and the sealing region through an adhesive layer. The adhesive layer is cured when in a flowable state to function as an adhesive. In a case where the moisture-proof protective layer is adhered, the adhesive layer enters a flowable state, and thus, the adhesive layer flows into the groove portion and fills at least a part of the inside of the groove portion.

### CROSS-REFERENCE TO RELATED APPLICATIONS

This application is a continuation application of International Application No. PCT/JP2015/058599, filed Mar. 20, 2015, the disclosure of which is incorporated herein by reference in its entirety. Further, this application claims priority from Japanese Patent Application No. 2014-070543, filed Mar. 28, 2014, the disclosure of which is incorporated herein by reference in its entirety.

### BACKGROUND OF THE INVENTION

1. Field of the Invention

The present invention relates to a radiation detecting device and a method for manufacturing the radiation detecting device.

2. Description of the Related Art

In the related art, a radiation imaging device that performs radiation imaging for medical diagnosis is known. In such a radiation imaging device, a radiation detecting device for detecting radiation passed through an object to generate a radiographic image is used.

As the radiation detecting device, there is a radiation detecting device that includes a substrate where pixels that generate electric charges according to emitted light are provided and a phosphor layer that is formed on the substrate and converts radiation into light to emit the light onto the substrate. In order to protect the phosphor layer formed on the substrate, a surface thereof is covered with a protective film or the like (see JP2013-118220A and JP2006-343277A).

### SUMMARY OF THE INVENTION

When forming a phosphor layer in a partial region of a substrate, in a case where the phosphor layer is covered with a protective film or the like with an adhesive therebetween, a liquid reservoir may be generated due to the adhesive in an edge portion of the phosphor layer and the thickness of an adhesive layer may increase in a region of the edge portion. In such a case, when the thickness of the adhesive layer increases, there is a concern that moisture may easily intrude and thus durability of the radiation detecting device may deteriorate.

The invention provides a radiation detecting device and a method for manufacturing the radiation detecting device capable of preventing intrusion of moisture and enhancing durability performance of the radiation detecting device.

According to a first aspect of the invention, there is provided a radiation detecting device including: a substrate on which a plurality of pixels that receive light generated by emitted radiation and generate electric charges is arranged; a first protective layer that is provided on the substrate; a phosphor layer that is provided on the first protective layer and receives the radiation to generate the light; and a second protective layer that is formed to cover the phosphor layer with a resin therebetween, in which a groove portion that is filled with the resin is formed in the first protective layer, in a sealing region that surrounds a region where the phosphor layer is provided.

According to a second aspect of the invention, in the radiation detecting device according to the first aspect, the groove portion may surround the phosphor layer.

According to a third aspect of the invention, in the radiation detecting device according to the first aspect, the groove portion may be formed along each outer peripheral side of the phosphor layer.

According to a fourth aspect of the invention, in the radiation detecting device according to the third aspect, an edge portion of the groove portion may be formed to be aligned with the outer peripheral side.

According to a fifth aspect of the invention, in the radiation detecting device according to any one of the first to fourth aspects, the resin may be a resin that is curable according to application of stress.

According to a sixth aspect of the invention, in the radiation detecting device according to any one of the first to fifth aspects, the resin may be a hot melt resin or a photocurable resin.

According to a seventh aspect of the invention, in the radiation detecting device according to any one of the first to sixth aspects, the groove portion may be provided at a position closer to an inner periphery than to an outer periphery of the sealing region, in the sealing region.

According to an eighth aspect of the invention, in the radiation detecting device according to any one of the first to seventh aspects, the groove portion may pass through the first protective layer, and may reach the inside of the substrate.

According to a ninth aspect of the invention, there is provided a method for manufacturing a radiation detecting device, the method including: a preparation process of preparing a substrate on which a first protective layer is formed and a plurality of pixels that receives light generated by emitted radiation and generates electric charges is arranged; a groove portion formation process of forming, prior to a phosphor layer formation process of forming a phosphor layer that receives the radiation to generate the light, a groove portion in the first protective layer in a sealing region that surrounds a region where the phosphor layer is provided; a phosphor layer formation process of forming the phosphor layer on the first protective layer; and a second protective layer formation process of forming a second protective layer to cover the phosphor layer with a resin therebetween.

According to the above-described aspects of the invention, it is possible to provide a radiation detecting device and a method for manufacturing the radiation detecting device capable of preventing intrusion of moisture and enhancing durability performance of the radiation detecting device.

### BRIEF DESCRIPTION OF THE DRAWINGS

FIG. 1 is a diagram showing an example of a specific configuration of a radiation detecting device according to a first embodiment.

FIG. 2 is a plan view illustrating an example of a structure of the radiation detecting device shown in FIG. 1.

FIG. 3 is an A-A sectional view of the radiation detecting device shown in FIG. 2.

FIG. 4 is a plan view of the radiation detecting device of the first embodiment when seen from a side where a phosphor layer is provided.

FIG. 5 is a B-B sectional view of an example of the radiation detecting device of the first embodiment shown in FIG. 4.

FIG. 6 is a flowchart illustrating an example of a flow of a manufacturing process of the radiation detecting device of the first embodiment.

FIG. 7 is a B-B sectional view of another example of the radiation detecting device of the first embodiment shown in FIG. 4.

FIG. 8 is a B-B sectional view of an example of a radiation detecting device according to a second embodiment.

FIG. 9 is a B-B sectional view of an example of a radiation detecting device according to a third embodiment.

FIG. 10 is a plan view of a radiation detecting device according to a fourth embodiment when seen from a side where a phosphor layer is provided.

FIG. 11 is a sectional view of an example of a radiation detecting device according to a comparative example.

### DESCRIPTION OF THE PREFERRED EMBODIMENTS

Hereinafter, embodiments of the invention will be described with reference to the accompanying drawings. The embodiments do not limit the invention.

### First Embodiment

A radiation detecting device of a first embodiment has a function of receiving radiation passed though an object and outputting image information indicating a radiographic image of the object. The radiation detecting device includes a photoelectric conversion substrate and a phosphor layer which is a scintillator that receives radiation and emits light.

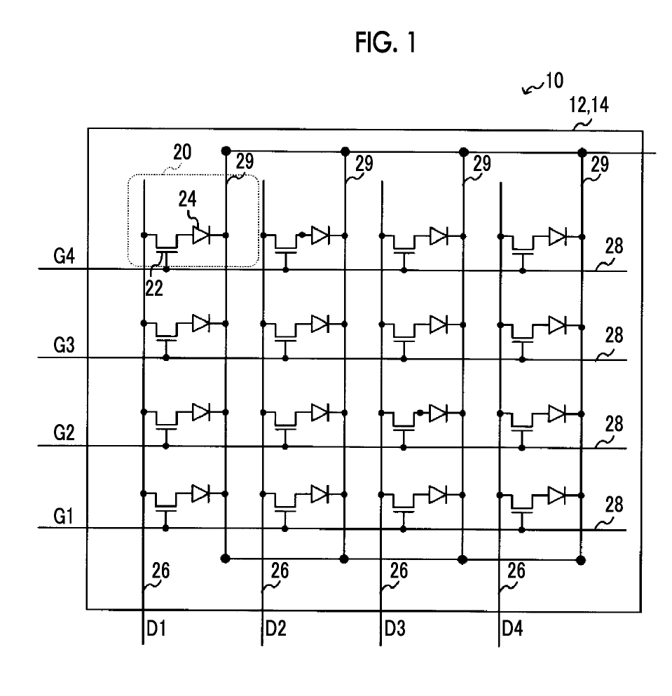

FIG. 1 shows an example of a specific configuration of the radiation detecting device of this embodiment.

A radiation detecting device 10 comprises a photoelectric conversion substrate 12, and the photoelectric conversion substrate 12 includes a thin film transistor (TFT) substrate 14 on which plural pixels 20 are formed. As shown in FIG. 1, the TFT substrate 14 of the photoelectric conversion substrate 12 includes the plural pixels 20 that include a sensor unit 24 and a switch element 22. The sensor unit 24 receives light generated in a phosphor layer to generate electric charges. The switch element 22 reads the electric charges accumulated by the sensor unit 24. A thin film transistor or the like may be used as a specific example of the switch element 22. Hereinafter, the switch element is referred to as a “TFT”.

The plural pixels 20 are arranged in a matrix form in one direction (a scanning interconnect direction corresponding to a transverse direction in FIG. 1, which is hereinafter referred to as a “row direction”) and a crossing direction (a signal interconnect direction corresponding to a longitudinal direction in FIG. 1, which is hereinafter referred to as a “column direction”) with respect to the row direction. Arrangement of the pixels 20 is briefly shown in FIG. 1, but for example, 1024×1024 pixels 20 are arranged in the row direction and the column direction.

Further, in the radiation detecting device 10, plural scanning interconnects 28 (G1 to G4) for controlling on/off of the TFT 22 and plural signal interconnects 26 (D1 to D4) provided for each pixel 20, from which electric charges accumulated by the sensor unit 24 are read, alternately intersect each other.

In the sensor unit 24 of each pixel 20, a common interconnect 29 is provided in a interconnect direction of the signal interconnect 26 in order to apply a bias voltage to each pixel 20. The bias voltage is applied from a power source (not shown) through the common interconnect 29.

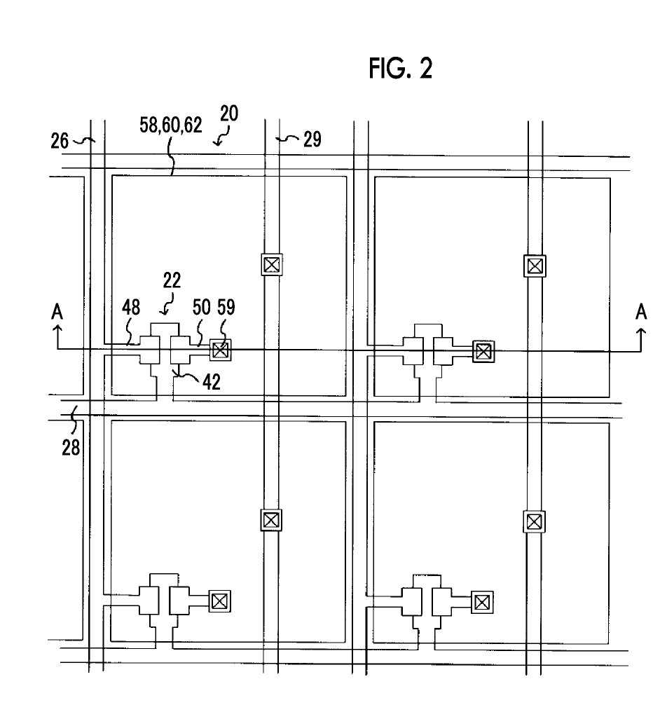

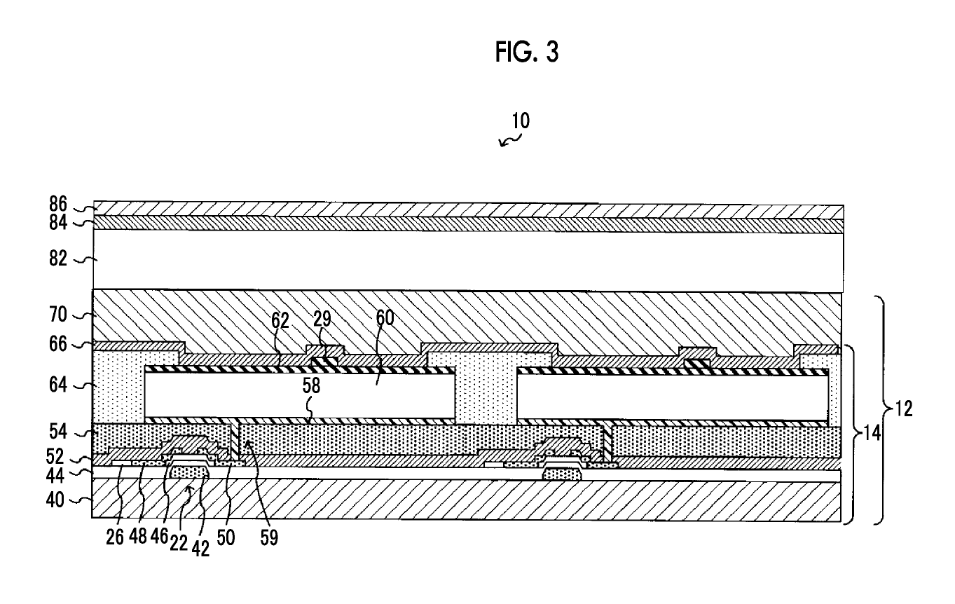

FIG. 2 shows a plan view of the radiation detecting device 10 shown in FIG. 1. Further, FIG. 3 shows an A-A sectional view of the radiation detecting device 10 shown in FIG. 2. In FIG. 2, a phosphor layer 82 is not shown.

As shown in FIG. 3, the radiation detecting device 10 is configured so that the scanning interconnect 28, a gate electrode 42, and the pixel 20 are formed on an insulating substrate 40 made of non-alkali glass or the like. The gate electrode 42 of the TFT 22 is connected to the scanning interconnect 28 (see FIG. 2). An interconnect layer (hereinafter, referred to as a “first signal interconnect layer”) in which the scanning interconnect 28 and the gate electrode 42 are formed is formed of a laminated film made of Al or Cu, or a material using Al or Cu as a main component, but the invention is not limited thereto.

An insulating film 44 is formed on one surface of the first signal interconnect layer, and a portion thereof disposed on the gate electrode 42 acts as a gate insulating film in the TFT 22. The insulating film 44 is formed of SiNₓ or the like, for example, and is formed through chemical vapor deposition (CVD), for example.

A semiconductor active layer 46 is formed in an island shape on the gate electrode 42 on the insulating film 44. The semiconductor active layer 46 is a channel portion of the TFT 22, and for example, is formed of an amorphous silicon film.

A source electrode 48 and a drain electrode 50 are formed on an upper layer thereof. The signal interconnect 26 together with the source electrode 48 and the drain electrode 50 are formed on the interconnect layer on which the source electrode 48 and the drain electrode 50 are formed. The source electrode 48 of the TFT 22 of the pixel 20 is connected to the signal interconnect 26. An interconnect layer (hereinafter, referred to as a “second signal interconnect”) in which the source electrode 48, the drain electrode 50, and the signal interconnect 26 are formed is formed of a laminated film Al or Cu, or a material using Al or Cu as a main component, but the invention is not limited thereto. An impurity-added semiconductor layer (not shown) based on impurity-added amorphous silicon or the like is formed between the source electrode 48 and the drain electrode 50, and the semiconductor active layer 46. In the TFT 22, the source electrode 48 and the drain electrode 50 are reversed according to polarities of collected and accumulated electric charges by a lower electrode 58 (which will be described later).

Hereinafter, the first signal interconnect layer and the second signal interconnect layer may be generally referred to as a TFT interconnect layer 90.

On an approximately entire surface of a region (approximately entire region) in which the pixel 20 on the substrate 40 is provided, covered with the second signal interconnect, a TFT protective film layer 52 is formed to protect the TFT 22 and the signal interconnect 26. The TFT protective film layer 52 is formed of SiNₓ or the like, and is formed through CVD, for example.

A coating type first flattening film 54 is formed on the TFT protective film layer 52. The first flattening film 54 is formed of a photosensitive organic material of a low dielectric constant (relative dielectric constant cr=2 to 4), for example, with a film thickness of 1 μm to 10 μm, preferably, 1 μm to 5 μm. As such an organic material, for example, a material obtained by mixing a naphthoquinone diazide-based positive photosensitizer into a base polymer formed of a copolymer of positive photosensitive acrylic-based resin:methacrylic acid and glycidyl methacrylate is used.

The first flattening film 54 has a function as a flattening film, and has an effect of flattening a step of a lower layer. Further, the first flattening film 54 also has an effect of reducing capacitance between metals arranged on an upper layer and a lower layer of the first flattening film 54. A contact hole 59 is formed on the first flattening film 54.

The lower electrode 58 of the sensor unit 24 is formed on the first flattening film 54 to cover a pixel region where the pixel 20 is formed while filling the contact hole 59. The lower electrode 58 is connected to the drain electrode 50 of the TFT 22 through the contact hole 59. A material of the lower electrode 58 is not particularly limited as long as it has conductivity in a case where the semiconductor layer 60 (which will be described later) has a thickness of about 1 μm. Thus, the lower electrode 58 may be formed of a conductive metal such as an Al-based material, Indium Tin Oxide (ITO), and the like.

On the other hand, in a case where the film thickness of the semiconductor layer 60 is thin (about 0.2 μm to about 0.5 μm), since absorption of light is not sufficient in the semiconductor layer 60, in order to prevent an increase in current leakage due to light emission to the TFT 22, it is preferable that the lower electrode 58 is formed of an alloy in which a light shielding metal is a main component, or a laminated film.

The semiconductor layer 60 that functions as a photodiode is formed on the lower electrode 58. In this embodiment, a photodiode of a PIN structure in which an n+layer, an i layer, and a p+layer (n+amorphous silicon, amorphous silicon, and p+amorphous silicon, which are not shown in the figure) are laminated from the substrate is employed as the semiconductor layer 60. When light is emitted to the i layer, electric charges (a pair of a free electron and a free hole) are generated in the layer i layer. The n+layer and the p+layer function as contact layers, and electrically connects the lower electrode 58 and the upper electrode 62 (which will be described later) with the i layer.

The upper electrode 62 is individually formed on the semiconductor layer 60. A material having a high light transmittance such as ITO or Indium Zinc Oxide (IZO) is used as the upper electrode 62, for example. The sensor unit 24 of the radiation detecting device 10 of this embodiment includes the upper electrode 62, the semiconductor layer 60, and the lower electrode 58.

A second flattening film 64 for flattening irregularities formed by the semiconductor layer 60 is formed on the first flattening film 54. In this embodiment, the second flattening film 64 is formed of the same material as that of the first flattening film 54 with the same thickness as that thereof. The invention is not limited thereto, and the second flattening film 64 may be formed of a material different from that of the first flattening film 54 with a thickness different from that thereof. Here, the material and thickness of the second flattening film 64 may be the same material and thickness of the first flattening film 54.

In the radiation detecting device 10 of this embodiment, a protective film 66 is formed on the second flattening film 64 to cover a side surface of the sensor unit 24 and an edge portion of the upper electrode 62.

The TFT substrate 14 formed in this way corresponds to an example of a substrate of the disclosed technique. A surface organic film 70 which is an example of a first protective film of the disclosed technique is formed on the TFT substrate 14. Polyimide is preferably used as the surface organic film 70, for example. Preferably, the film thickness of the surface organic film 70 is 1 μm to 100 μm, for example.

In this embodiment, a substrate in which surface organic film 70 is formed on the TFT substrate 14 is referred to as the photoelectric conversion substrate 12.

A phosphor layer 82 is formed on the photoelectric conversion substrate 12. In this embodiment, a scintillator is used as the phosphor layer 82. As the scintillator, preferably, a scintillator that generates fluorescence having a wavelength region of a relatively wide range, capable of generating light having an absorbable wavelength range is used. As such a scintillator, CsI:Na, CaWO₄, YtaO₄:Nb, BaFx:Eu (X is Br or Cl), LaOBr:Tm, GOS (Gd₂O₂S:Pr), or the like may be used. Specifically, in a case where imaging is performed using X-rays as radiation, it is preferable to use cesium iodide (CsI), and it is more preferable to use CsI:Tl (cesium iodide to which thallium is added) or CsI:Na of which a light emission spectrum in X-ray emission is 400 nm to 700 nm. A light emission peak wavelength in a visible light range of CsI:Tl is 565 nm. Further, in a case where a scintillator including CsI is used as the scintillator, it is preferable to use a scintillator formed as a columnar crystal structure of a strip form by a vacuum deposition method. Further, preferably, the thickness of the phosphor layer 82 is 100 μm to 800 μm.

A moisture-proof protective layer 86 which is an example of a second protective layer of the disclosed technique is formed on the phosphor layer 82 through an adhesive layer 84 which is an example of a resin of the disclosed technique. The adhesive layer 84 is not particularly limited as long as it is a resin that is curable according to application of stress (stimulus) from a flowable state, but a photocurable resin or a hot melt resin is preferably used. Normally, as the photocurable resin, a resin that is normally in a flowable state and is curable by visible light or invisible light such as infrared rays may be used. As a specific example, urethane acrylate, acrylic resin acrylate, epoxy acrylate, or the like may be used.

Further, as the hot melt resin, a resin which is normally solid and changes into a flowable state as according to application of heat may be used. As a specific example, a thermosetting plastic such as ethylene-vinyl acetate copolymer resin (EVA), ethylene-acrylic acid copolymer resin (EAA), ethylene-ethyl acrylate copolymer resin (EEA), or ethylene-methyl methacrylate copolymer (EMMA) may be used.

Further, the material is not limited to the photocurable resin or the hot melt resin, and any resin that is cured when in a flowable state may be used. For example, a thermosetting resin may be used. A viscosity in the flowable state is preferably 100 Pa·S to 10000 Pa·S.

The thickness of the adhesive layer 84 is preferably 5 μm to 50 μm.

A moisture-proof protective layer 86 has a function of protecting the radiation detecting device 10 from moisture or the like. In FIG. 3, an example in which the moisture-proof protective layer 86 is a single layer is shown, but in this embodiment, as a specific example, a two-layered moisture-proof protective layer 86 including a protective layer based on an organic film and a reflecting layer is used. The protective layer is provided on a side where the moisture-proof protective layer 86 is in contact with the adhesive layer 84. An organic film of a melting point higher than that of the adhesive layer 84 may be used as the protective layer. As a specific example, polyethylene terephthalate (PET), polyphenylene sulfide (PPS), biaxially oriented polypropylene (OPP), polyethylene naphthalate (PEN), polyimde (PI), or the like may be used.

Further, as the reflecting layer which is a top layer of the radiation detecting device 10, Al, an AL alloy, Ag, or the like may be used.

The thickness of the moisture-proof protective layer 86 is preferably 10 μm to 200 μm.

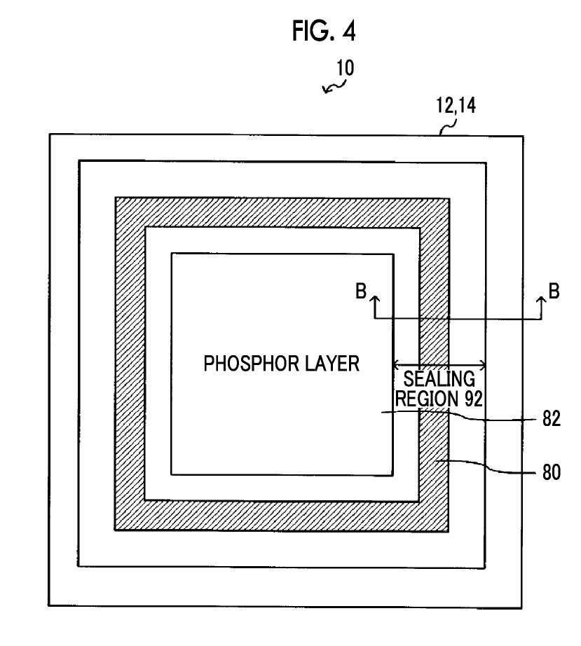

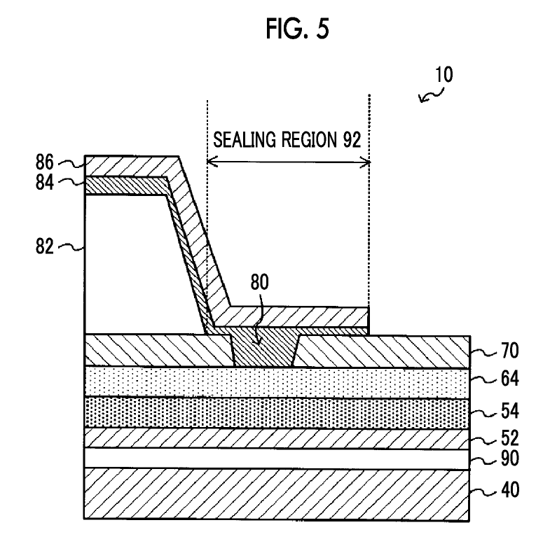

FIG. 4 shows a plan view of the radiation detecting device 10 when seen from a side where the phosphor layer 82 is provided. Further, FIG. 5 is a B-B sectional view of the radiation detecting device 10 shown in FIG. 4.

The phosphor layer 82 is provided in a central region on the photoelectric conversion substrate 12 (TFT substrate 14). The phosphor layer 82 is formed to cover a region (pixel region) where the pixel 20 of the TFT substrate 14 is formed. As the size (size on the surface of the photoelectric conversion substrate 12) of the phosphor layer 82, specifically, 43.2 cm×43.2 cm, 35.6 cm×43.2 cm, 27.9 cm×30.5 cm, 25.4 cm×30.5 cm, or the like may used.

A sealing region 92 is provided between an outer edge portion of the phosphor layer 82 on the photoelectric conversion substrate 12 and an edge portion of the photoelectric conversion substrate 12. The sealing region 92 surrounds the periphery of the phosphor layer 82. The sealing region 92 refers to a region on the photoelectric conversion substrate 12 covered with the moisture-proof protective layer 86 to seal the phosphor layer 82 by the moisture-proof protective layer 86. The sealing region 92 includes a region substantially provided due to flowing of the adhesive layer 84 and the moisture-proof protective layer 86 when sealing is performed using the moisture-proof protective layer 86 in addition to a region that is predetermined in design,. Further, an edge portion of the sealing region 92 close to the phosphor layer 82 is referred to as an inner periphery, and an edge portion thereof close to the photoelectric conversion substrate 12 (TFT substrate 14) is referred to as an outer periphery.

A groove portion 80 is provided in the sealing region 92. From a viewpoint of reducing a liquid reservoir formed by the adhesive layer 84 in an edge portion of the phosphor layer 82, it is preferable that the groove portion 80 is provided at a position close to an outer edge (hereinafter, referred to as an edge portion) of the phosphor layer 82. More preferably, the groove portion 80 is provided at a position closer to the edge portion of the phosphor layer 82 than to the edge portion of the photoelectric conversion substrate 12. Most preferably, it is preferable that the groove portion 80 is provided at a position closer to the inner periphery of the sealing region 92 than to the outer periphery of the sealing region 92.

In a case where the groove portion 80 is provided outside the sealing region 92, there is a concern that a region where the adhesive layer 84 is in contact with the outside (outside air) increases and moisture intrudes from the region being in contact with the outside. Thus, the groove portion 80 is provided in the sealing region 92.

Further, the groove portion 80 is provided in parallel with the edge portion of the photoelectric conversion substrate 12. Here, the “parallel” includes ignorable variation due to an error in design or the like. In a case where the groove portion 80 is provided in a direction intersecting the edge portion of the photoelectric conversion substrate 12, moisture-proof performance in a portion where the groove portion 80 is provided may deteriorate. As a result, there is a concern that moisture-proof performance of the radiation detecting device 10 deteriorates. Thus, it is preferable that the groove portion 80 is provided in parallel with the edge portion of the photoelectric conversion substrate 12.

As a specific example of a distance (width) from the edge portion of the phosphor layer 82 to the outer periphery of the sealing region 92, 1 mm to 10 mm may be used. It is preferable that the width of the groove portion 80 is 25% to 75% of the width of the sealing region 92. More preferably, the width of the groove portion 80 is about 50% of the width of the sealing region 92.

The groove portion 80 of this embodiment is provided in the surface organic film 70, as shown in FIG. 5. More preferably, the groove portion 80 passes through the surface organic film 70 to reach the surface of the second flattening film 64.

Next, a method for manufacturing the radiation detecting device 10 will be described.

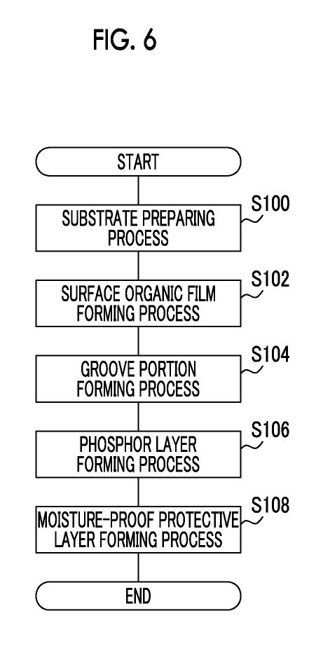

FIG. 6 is a flowchart illustrating an example of a flow of a manufacturing process of the radiation detecting device 10.

First, in step S100, a substrate preparation process is performed. In the substrate preparation process, the TFT substrate 14 is prepared. The TFT substrate 14 may be prepared through preparation of the radiation detecting device 10 which is manufactured in advance, or may be manufactured using the substrate 40 as follows.

In a case where the TFT substrate 14 is manufactured, first, the TFT 22 is formed on the substrate 40.

Then, the TFT protective film layer 52 is formed on the substrate 40 on which the TFT 22 is formed, and then, the first flattening film 54 is formed thereon.

Then, the contact hole 59 is formed in the first flattening film 54. The lower electrode 58 is formed while filling the contact hole 59, and then, the semiconductor layer 60 and the upper electrode 62 are formed thereon. In this way, the sensor unit 24 is formed.

Then, in order to flatten irregularities formed by the lower electrode 58, the semiconductor layer 60, and the upper electrode 62, the second flattening film 64 is formed.

Then, the common interconnect 29 is formed on the upper electrode 62.

Then, the protective film 66 is formed on the entire surface of the second flattening film 64, the upper electrode 62, and the common interconnect 29.

If the TFT substrate 14 can be prepared, in the next step S102, the surface organic film 70 is formed on the TFT substrate 14 by a surface organic film formation process. Instead of the process of step S102, the photoelectric conversion substrate 12 which is manufactured in advance may be prepared. Steps S100 and S102 correspond to an example of a preparation process of the disclosed technique.

In the next step S104, the groove portion 80 is formed by a groove formation process. In this embodiment, the groove portion 80 is formed by processing the surface organic film 70. For example, the processing of the surface organic film 70 may be performed with high accuracy in the unit of several micrometers by using a photolithography process.

As a specific method, a method for bonding the surface organic film 70 (a film made of polyimide or the like) where the groove portion 80 is formed by cutting in advance may be used. Further, for example, a method of masking the corresponding portion, performing a surface protection process using a crystalline polymer or the like, and performing etching may be used, for example.

In the next step S106, the phosphor layer 82 is formed on the photoelectric conversion substrate 12 by a phosphor layer formation process. As a method for forming the phosphor layer 82, vacuum deposition may be used.

In the next step S108, the moisture-proof protective layer 86 is formed through the adhesive layer 84 by a moisture-proof protective layer formation process to cover the phosphor layer 82 and the sealing region 92.

In a case where the adhesive layer 84 is made of a photocurable resin, the adhesive layer 84 is coated in the phosphor layer 82 and the sealing region 92, and then, light is emitted thereto from the side of the substrate 40 of the TFT substrate 14, so that the adhesive layer 84 is cured to cause the moisture-proof protective layer 86 to adhere thereto. In a case where the adhesive layer 84 is made of a hot melt resin, the phosphor layer 82 is covered with the adhesive layer 84 and the moisture-proof protective layer 86, and then, heating and pressurization are performed, so that the adhesive layer 84 is melted to cause the moisture-proof protective layer 86 to adhere thereto.

In both cases, when the moisture-proof protective layer 86 is adhered through the adhesive layer 84, the adhesive layer 84 enters a flowable state, and thus, the adhesive layer 84 flows into the groove portion 80 and fills the inside of the groove portion 80. The inside of the groove portion 80 may not be entirely filled, and it is sufficient if the adhesive layer 84 at least enters the inside of the groove portion 80. For example, the adhesive layer 84 may fill a part of the inside of the groove portion 80. As the adhesive layer 84 enters the inside of the groove portion 80, it is possible to prevent a liquid reservoir of the adhesive layer 84 from being formed in the edge portion of the phosphor layer 82.

In this way, the radiation detecting device 10 of this embodiment is manufactured.

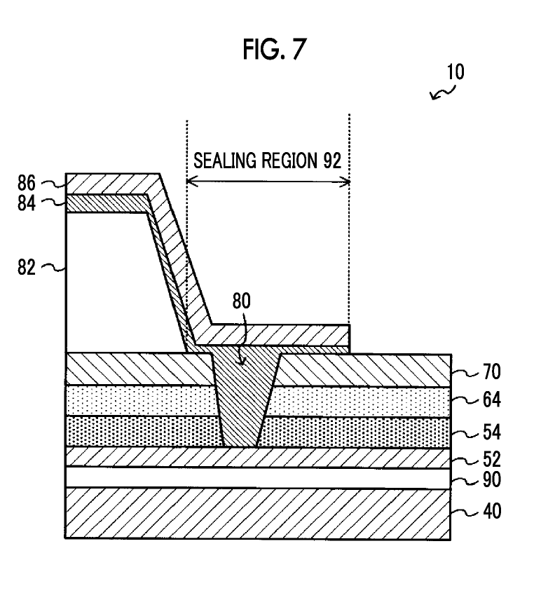

In this embodiment, an example in which the groove portion 80 is formed to pass through the surface organic film 70 and to reach the surface of the surface organic film 70 is shown, but the invention not limited thereto. For example, as shown in FIG. 7, the groove portion 80 may be formed to pass through the surface organic film 70, the second flattening film 64, and the first flattening film 54 and to reach the surface of the TFT protective film layer 52. In such a case, in the groove formation process of step S104, etching may be performed until the groove portion 80 reaches the surface of the TFT protective film layer 52.

In the radiation detecting device 10 shown in FIG. 7, the depth of the groove portion 80 is deeper than that of the radiation detecting device 10 shown in FIG. 5. The width of the groove portion 80 is limited depending on the width of the sealing region 92, but since the size of the inside of the groove portion 80 can be set to be larger without enlarging the width of the groove portion 80 compared with that shown FIG. 5, it is possible to increase the amount of the adhesive layer 84 that flows into the inside of the groove portion 80. Thus, in the radiation detecting device 10 of this embodiment, it is possible to make the adhesive layer 84 of the edge portion of the phosphor layer 82 thinner.

### Second Embodiment

Next, a second embodiment will be described. In the radiation detecting device 10 of this embodiment, since the groove portion 80 is different from that of the first embodiment, the groove portion 80 will be described. The same reference numerals are given to the same portions as in the radiation detecting device 10 according to the first embodiment, and detailed description thereof will not be repeated.

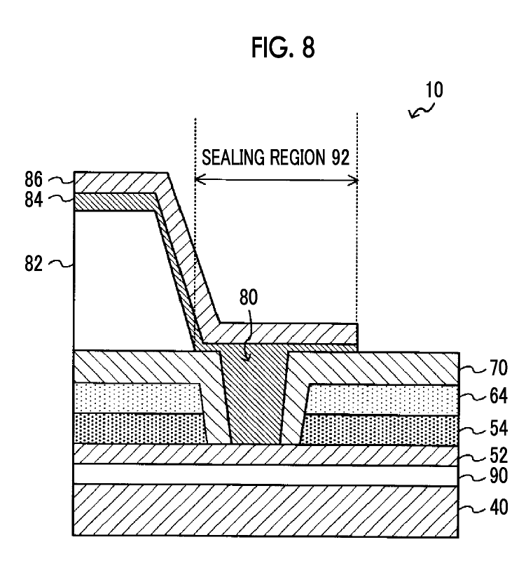

FIG. 8 is a sectional view corresponding to a B-B section in FIG. 4 in the first embodiment. In the radiation detecting device 10 of this embodiment shown in FIG. 8, the groove portion 80 passes through the surface organic film 70, the second flattening film 64, and the first flattening film 54, and reaches the surface of the TFT protective film layer 52. Further, the surface organic film 70 is formed to cover the top of the second flattening film 64 and an inner side wall of the groove portion 80.

When forming the groove portion 80 in this way, in the surface organic film formation process of step S102 in the manufacturing process of the radiation detecting device 10, etching is performed in portions of the first flattening film 54 and the second flattening film 64 corresponding to the groove portion 80 to eliminate the first flattening film 54 and the second flattening film 64. Then, the surface organic film 70 is formed on the photoelectric conversion substrate 12. Then, etching is performed in a portion corresponding to a bottom portion of the groove portion 80 to eliminate the surface organic film 70, so that the surface of the TFT protective film layer 52 may be exposed.

The manufacturing method is not limited thereto. For example, whenever the first flattening film 54 and the second flattening film 64 are formed, sequentially, portions thereof corresponding to the groove portion 80 may be formed through etching. Specifically, etching is performed in a portion of the first flattening film 54 corresponding to the groove portion 80 to eliminate the first flattening film 54 after the first flattening film 54 is formed. Further, the second flattening film 64 is formed. After the second flattening film 64 is formed, etching is performed in a portion thereof corresponding to the groove portion 80 to eliminate the second flattening film 64.

In the radiation detecting device 10 shown in FIG. 8, since the depth of the groove portion 80 is deeper than that of the radiation detecting device 10 shown in FIG. 5, similar to the radiation detecting device 10 shown in FIG. 7, it is possible to increase the amount of the adhesive layer 84 that flows into the inside of the groove portion 80. Thus, in the radiation detecting device 10 of this embodiment, it is possible to make the adhesive layer 84 in the edge portion of the phosphor layer 82 thinner. Further, in the radiation detecting device 10 of this embodiment, it is possible to protect the surfaces of the first flattening film 54 and the second flattening film 64 by the surface organic film 70, compared with the radiation detecting device 10 shown in FIG. 7.

### Third Embodiment

Next, a third embodiment will be described. In the radiation detecting device 10 of this embodiment, since the groove portion 80 is different from that of each of the above-described embodiments, the groove portion 80 will be described. The same reference numerals are given to the same portions as in the radiation detecting device 10 according to the first embodiment, and detailed description thereof will not be repeated.

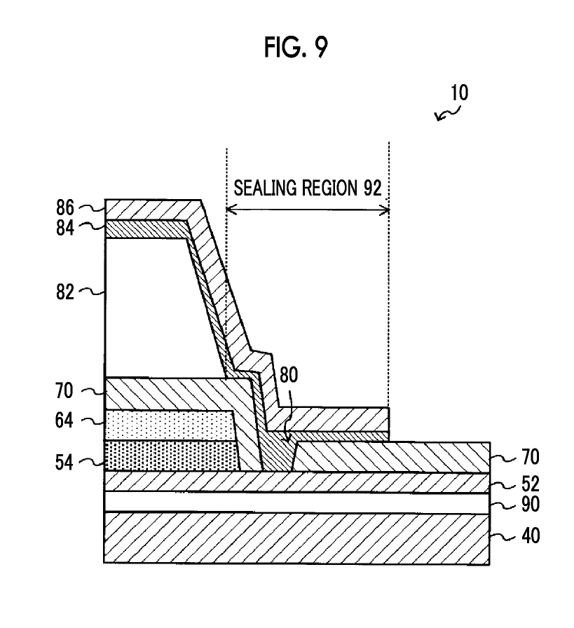

FIG. 9 is a sectional view corresponding to the B-B section in FIG. 4 according to the first embodiment. In the radiation detecting device 10 of this embodiment shown in FIG. 9, the groove portion 80 passes through the surface organic film 70, the second flattening film 64, and the first flattening film 54, and reaches the surface of the TFT protective film layer 52.

Further, in the radiation detecting device 10 of this embodiment, a configuration outside the sealing region 92 of the photoelectric conversion substrate 12, more specifically, a configuration from the groove portion 80 to the edge portion of the photoelectric conversion substrate 12 is different from that of the first embodiment.

As shown in FIG. 9, in the radiation detecting device 10 of this embodiment, the first flattening film 54 and the second flattening film 64 are not provided from the groove portion 80 to the edge portion of the photoelectric conversion substrate 12, and the surface organic film 70 is formed on the TFT protective film layer 52.

That is, in the radiation detecting device 10 of this embodiment, the surface organic film 70 is formed to cover the first flattening film 54 and the second flattening film 64 in a partial region where the phosphor layer 82 is provided, using the groove portion 80 as a boundary. Further, the surface organic film 70 is formed to cover the TFT protective film layer 52 in a region from the groove portion 80 to the edge portion of the TFT substrate 14.

When forming the groove portion 80 in this way, in the surface organic film formation process of step S102 in the manufacturing process of the radiation detecting device 10, etching is performed in portions corresponding to the sealing region 92 and a region from the sealing region 92 to the edge portion of the photoelectric conversion substrate 12 to eliminate the first flattening film 54 and the second flattening film 64. Then, the surface organic film 70 is formed on the photoelectric conversion substrate 12. Then, etching is performed in a bottom portion of the groove portion 80, so that the surface of the TFT protective film layer 52 may be exposed.

The manufacturing method is not limited thereto. For example, whenever the first flattening film 54 and the second flattening film 64 are formed, the portions thereof corresponding to the sealing region 92 and the region from the sealing region 92 to the edge portion of the photoelectric conversion substrate 12 may be sequentially eliminated. Specifically, after the first flattening film 54 is formed, etching is performed in a portion thereof corresponding to the sealing region 92 and the region from the sealing region 92 to the edge portion of the photoelectric conversion substrate 12 to eliminate the first flattening film 54. Further, the second flattening film 64 is formed. After the second flattening film 64 is formed, etching is performed in a portion thereof corresponding to the sealing region 92 and the region from the sealing region 92 to the edge portion of the photoelectric conversion substrate 12 to eliminate the second flattening film 64.

In the radiation detecting device 10 shown in FIG. 9, an example in which the first flattening film 54 and the second flattening film 64 are not provided from the groove portion 80 to the edge portion of the photoelectric conversion substrate 12, but the invention is not limited thereto. Only one of the first flattening film 54 and the second flattening film 64 may not be provided (may be eliminated).

In the radiation detecting device 10 shown in FIG. 9, a step is generated between a region of the surface organic film 70 corresponding to a lower part of the phosphor layer 82 and the sealing region 92, and a portion of the groove portion 80 on the side of the phosphor layer 82 is inclined compared with the configurations of the above-described embodiments. Since the inclination is sealed by the moisture-proof protective layer 86 through the adhesive layer 84, it is possible to make the adhesive layer 84 in the inclined portion thinner. Thus, in the radiation detecting device 10 of this embodiment, it is possible to prevent intrusion of moisture, and to reliably perform sealing using the moisture-proof protective layer 86.

### Fourth Embodiment

Next, a fourth embodiment will be described. In the radiation detecting device 10 of this embodiment, since the shape of the groove portion 80 is different from that of each of the above-described embodiments, the groove portion 80 will be described. The same reference numerals are given to the same portions as in the radiation detecting device 10 according to the first embodiment, and detailed description thereof will not be repeated.

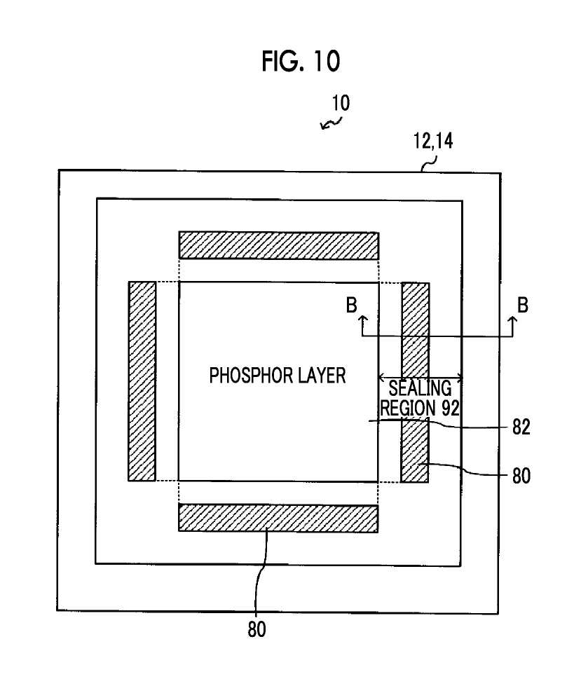

FIG. 10 shows a plan view of the radiation detecting device 10 according to this embodiment when seen from a side where the phosphor layer 82 is provided. In the radiation detecting device 10 of the first embodiment, the groove portion 80 surrounds the phosphor layer 82 (see FIG. 4). On the other hand, in the radiation detecting device 10 of this embodiment, the groove portion 80 is formed in parallel with an edge portion of the photoelectric conversion substrate 12 along an outer peripheral side of the phosphor layer 82. Specifically, as shown in FIG. 10, since the phosphor layer 82 is formed in a rectangular shape, four groove portions 80 are provided in parallel with the edge portions of the photoelectric conversion substrate 12 along four sides of the phosphor layer 82. Here, the “parallel” includes ignorable variation due to an error in design or the like.

It is preferable that the length of the groove portion 80 along the side of the phosphor layer 82 is equal to that of the side of the phosphor layer 82. Further, the position of the phosphor layer 82 in the width direction of the sealing region 92 is similar to the first embodiment (see FIG. 4). On the other hand, it is preferable that the position of the groove portion 80 in the direction along the side of the phosphor layer 82 is set so that the side of each phosphor layer 82 and the side of the edge portion of the groove portion 80 are aligned with each other (see broken lines in FIG. 10). The alignment of the side of the phosphor layer 82 and the edge portion of the groove portion 80 includes ignorable variation due to an error in design or the like.

By forming the radiation detecting device 10 as shown in FIG. 10, it is possible to reduce the size of a region on the photoelectric conversion substrate 12 where the groove portion 80 is provided, compared with the radiation detecting device 10 of the embodiments.

As described above, in the radiation detecting device 10 of the respective embodiments, the groove portion 80 is provided in the sealing region 92 on the photoelectric conversion substrate 12. The groove portion 80 is provided in the vicinity of the phosphor layer 82 formed on the photoelectric conversion substrate 12 or at a position along an outer edge periphery thereof. The moisture-proof protective layer 86 is provided to cover the phosphor layer 82 and the sealing region 92 through the adhesive layer 84.

The adhesive layer 84 is cured through a flowable state, and thus, functions as an adhesive. In a case where the moisture-proof protective layer 86 is adhered, since the adhesive layer 84 is in the flowable state, the adhesive layer 84 flows into the inside of the groove portion 80, and fills at least a part of the inside of the groove portion 80.

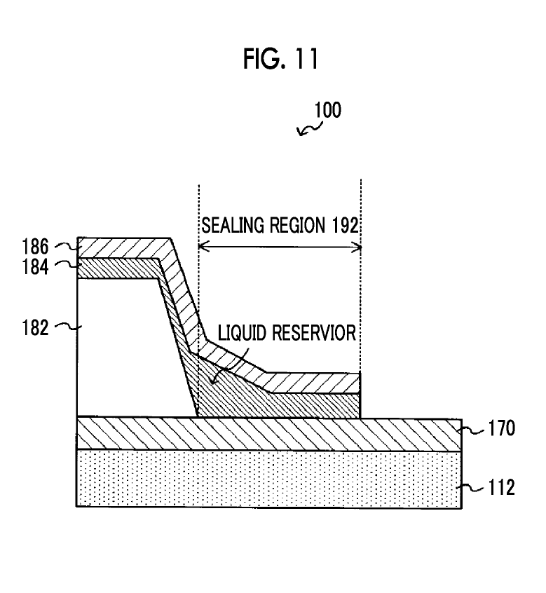

Thus, a liquid reservoir due to the adhesive layer 84 is generated at an edge portion of the phosphor layer 82, and thus, it is possible to prevent the thickness of the adhesive layer 84 in the edge portion of the phosphor layer 82 from increasing. As a comparative example with respect to the radiation detecting device 10 of the above-described embodiments, FIG. 11 shows a sectional view including an edge portion of a phosphor layer in a radiation detecting device in which a groove portion is not provided. In the radiation detecting device 100 of the comparative example shown in FIG. 11, similar to the radiation detecting device 10 of the above-described embodiments, a surface organic film 170 is formed on a photoelectric conversion substrate 112, and a phosphor layer 182 is provided on a photoelectric conversion substrate 112. Further, in the radiation detecting device 100 of the comparative example, a configuration in which a moisture-proof protective layer 186 is provided through an adhesive layer 184 to cover the phosphor layer 182 and a sealing region 192 is similar to that of the radiation detecting device 10 of the above-described embodiments. However, as understood from comparison between the radiation detecting device 100 shown in FIG. 11 and the radiation detecting device 10 of the above-described embodiments (see FIGS. 5, 7, 8, and 9), since the groove portion 80 is not provided in the radiation detecting device 100 of the comparative example, a liquid reservoir of the adhesive layer 184 is generated in an edge portion of a phosphor layer 182. In the radiation detecting device 100 of the comparative example, the liquid reservoir is generated in this way, the thickness of the adhesive layer 184 increases, and thus, moisture from the outside easily intrudes. Thus, there is a concern that durability performance of the radiation detecting device 100 of the comparative example deteriorates.

On the other hand, in the radiation detecting device 10 of the above-described embodiments, the groove portion 80 is provided in the sealing region 92 of the photoelectric conversion substrate 12. In a case where the moisture-proof protective layer 86 is adhered through the adhesive layer 84, since the adhesive layer 84 flows into the inside of the groove portion 80 in the flowable state, it is possible to prevent a liquid reservoir due to the adhesive layer 84 from being generated at an edge portion of the phosphor layer 82. Further, as the adhesive layer 84 flows into the inside of the groove portion 80, it is possible to reduce the thickness of the adhesive layer 84 in the sealing region 92. Accordingly, it is possible to prevent intrusion of moisture from the outside of the radiation detecting device 10, to thereby enhance durability performance of the radiation detecting device 10.

In the above-described embodiments, as shown in FIG. 1, a case where the pixels 20 are arranged on a matrix in two dimensions is described, but the arrangement of the pixels 20 is not limited thereto, and for example, may be arranged in one dimension or in a honeycomb form. In addition, the shape of the pixel is not limited, and may be a rectangular shape or a polygonal shape such as a hexagon.

Further, the shape or the like of the phosphor layer 82 is not limited to the above-described embodiments. In the above-described embodiments, a case where the shape is a rectangular shape is described, but for example, the shape may be a polygonal shape or a circular shape. It is sufficient if the phosphor layer 82 is provided to cover an upper surface of a region (pixel region) where the pixels 20 of the photoelectric conversion substrate 12 are provided.

In addition, the material of the surface organic film 70 is not limited to the above-described embodiments. For example, the material of the surface organic film 70 is exchangeable with a crystalline polymer material such as polyparaxylylene (Parylene: trademark of Union Carbide), polyurea, or polyamide.

Furthermore, the configuration, the operation and the like of the radiation detecting device 10 described in the embodiments are examples, and may be modified as necessary in a range without departing from the concept of the invention.

The disclosure of Japanese Patent Application No. 2014-070543 is entirely incorporated in this description by reference.

Entire documents, patent applications, and technical standards written in this description are incorporated in this description by reference to the same degree as in a case where the respective documents, patent applications, and technical standards are specifically and individually written to be incorporated by reference.

What is claimed is:

1. A radiation detecting device comprising:
a substrate on which a plurality of pixels that receives light generated by emitted radiation and generates electric charges is arranged;
a first protective layer that is provided on the substrate;
a phosphor layer that is provided on the first protective layer and receives the radiation to generate the light; and
a second protective layer that is formed to cover the phosphor layer with a resin therebetween,
wherein a groove portion that is filled with the resin is formed in the first protective layer, in a sealing region that surrounds a region where the phosphor layer is provided.

2. The radiation detecting device according to claim 1,
wherein the groove portion surrounds the phosphor layer.

3. The radiation detecting device according to claim 1,
wherein the groove portion is formed along each outer peripheral side of the phosphor layer.

4. The radiation detecting device according to claim 3,
wherein a length direction end of the groove portion is formed on a line of extension of an outer peripheral side of the phosphor layer that extends along a direction orthogonal to the length direction of the groove portion.

5. The radiation detecting device according to claim 1,
wherein the resin is a resin that is curable according to application of stress.

6. The radiation detecting device according to claim 2,
wherein the resin is a resin that is curable according to application of stress.

7. The radiation detecting device according to claim 3,
wherein the resin is a resin that is curable according to application of stress.

8. The radiation detecting device according to claim 1,
wherein the resin is a hot melt resin or a photocurable resin.

9. The radiation detecting device according to claim 2,
wherein the resin is a hot melt resin or a photocurable resin.

10. The radiation detecting device according to claim 3,
wherein the resin is a hot melt resin or a photocurable resin.

11. The radiation detecting device according to claim 1,
wherein the groove portion is provided at a position closer to an inner periphery than to an outer periphery of the sealing region, in the sealing region.

12. The radiation detecting device according to claim 2,
wherein the groove portion is provided at a position closer to an inner periphery than to an outer periphery of the sealing region, in the sealing region.

13. The radiation detecting device according to claim 3,
wherein the groove portion is provided at a position closer to an inner periphery than to an outer periphery of the sealing region, in the sealing region.

14. The radiation detecting device according to claim 1,
wherein the groove portion passes through the first protective layer, and reaches the inside of the substrate.

15. The radiation detecting device according to claim 2,
wherein the groove portion passes through the first protective layer, and reaches the inside of the substrate.

16. The radiation detecting device according to claim 3,
wherein the groove portion passes through the first protective layer, and reaches the inside of the substrate.

17. A method for manufacturing a radiation detecting device, the method comprising:
a preparation process of preparing a substrate on which a first protective layer is formed and a plurality of pixels that receives light generated by emitted radiation and generates electric charges is arranged;
a groove portion formation process of forming, prior to a phosphor layer formation process of forming a phosphor layer that receives the radiation to generate the light, a groove portion in the first protective layer in a sealing region that surrounds a region where the phosphor layer is provided;
a phosphor layer formation process of forming the phosphor layer on the first protective layer; and
a second protective layer formation process of forming a second protective layer to cover the phosphor layer with a resin therebetween.
